(19) United States
(12) Patent Application Publication
(10) Pub. No.: US 2019/0179185 A1
(43) Pub. Date: Jun. 13, 2019

(54) DISPLAY DEVICE

(71) Applicant: Samsung Display Co., Ltd., Yongin-si (KR)

(72) Inventors: Ho Kil OH, Seoul (KR); Kyung Min KIM, Seoul (KR); Kyeong Jong KIM, Suwon-si (KR); Heung Shik PARK, Seoul (KR); Ki Chul SHIN, Seongnam-si (KR); Dong-Chul SHIN, Hwaseong-si (KR); Jae-Soo JANG, Suwon-si (KR)

(21) Appl. No.: 16/058,979

(22) Filed: Aug. 8, 2018

(30) Foreign Application Priority Data
Dec. 7, 2017 (KR) 10-2017-0167717

(51) Int. Cl. G02F 1/1343; G02F 1/1335; H01L 27/12; G02F 1/1337

(52) U.S. Cl. CPC G02F 1/1343; G02F 1/133514; G02F 2201/123; H01L 27/1214; G02F 1/1337; G02F 1/133528

(57) ABSTRACT

A display device according to an exemplary embodiment includes: a thin film transistor array panel including a first pixel electrode connected to a first thin film transistor a second pixel electrode adjacent to the first pixel electrode and connected to a second thin film transistor; and a color conversion display panel overlapping the thin film transistor array panel, wherein the color conversion display panel includes a color conversion layer including a semiconductor nanocrystal and a transmissive layer, the thin film transistor array panel includes a first shielding electrode positioned between the first pixel electrode and the second pixel electrode and a second shielding electrode positioned adjacent to the first pixel electrode and separated from the first shielding electrode, and different voltages are applied to the first shielding electrode and the second shielding electrode.

### CROSS REFERENCE TO RELATED APPLICATION

This application claims priority from and the benefit of Korean Patent Application No. 10-2017-0167717, filed on Dec. 7, 2017, which is hereby incorporated by reference for all purposes as if fully set forth herein.

### BACKGROUND

### Field

Exemplary embodiments of the invention relate generally to a display device. More specifically, exemplary embodiments of the present invention relate to a display device with improved color reproducibility and luminance.

### Discussion of the Background

A liquid crystal display may include two field generating electrodes, a liquid crystal layer, a color filter, and a polarization layer. Light generated from a light source reaches a viewer after passing through the liquid crystal layer, the color filter, and the polarization layer. In this case, there is a problem that light loss is generated between the polarization layer and the color filter, etc. The light loss may also be generated in a display device such as an organic light emitting diode display as well as the liquid crystal display.

In order to implement a display device with reduced light loss and having high color reproducibility, a display device including a color conversion display panel using a semiconductor nanocrystal is proposed.

The above information disclosed in this Background section is only for understanding of the background of the inventive concepts, and, therefore, it may contain information that does not constitute prior art.

### SUMMARY

Exemplary embodiments relate to a display device with improved color reproducibility and luminance.

A display device according to an exemplary embodiment includes a thin film transistor array panel including a first pixel electrode connected to the thin film transistor and a second pixel electrode adjacent to the first pixel electrode and connected to a second thin film transistor; and a color conversion display panel overlapping the thin film transistor array panel. The color conversion display panel includes a color conversion layer including a semiconductor nanocrystal and a transmissive layer. The thin film transistor array panel includes a first shielding electrode positioned between the first pixel electrode and the second pixel electrode and a second shielding electrode positioned adjacent to the first pixel electrode and separated from the first shielding electrode. The first shielding electrode and the second shielding electrode are configured to receive different voltages.

The first shielding electrode may be configured to receive a voltage that may be larger than a voltage that the second shielding electrode is configured to receive.

The first shielding electrode may be configured to receive a higher voltage than the voltage applied to the first pixel electrode, and the second shielding electrode may be configured to receive a voltage that is the same as or lower than the voltage applied to the pixel electrode.

The first pixel electrode may include a first vertical stem part, a first horizontal stem part, and a first minute branch part, the first pixel electrode may be positioned between the first shielding electrode and the second shielding electrode, and the first vertical stem part may be positioned adjacent to the first shielding electrode.

The first horizontal stem part may be orthogonal at the center of the first vertical stem part.

The liquid crystal layer overlapping the first pixel electrode may include two domains with different arrangement directions of the liquid crystal molecules.

The second pixel electrode includes a second vertical stem part, a second horizontal stem part, and a second minute branch part. The second pixel electrode is positioned between the first shielding electrode and a different second shielding electrode, and the second vertical stem part of the second pixel electrode is positioned adjacent to the first shielding electrode. The first pixel electrode and the second pixel electrode may be symmetrical with reference to the first shielding electrode.

The first shielding electrode, the second shielding electrode, and the first pixel electrode may be positioned on a same layer.

Liquid crystal molecules positioned between the first vertical stem part and the first shielding electrode may be arranged parallel to liquid crystal molecules overlapping the first minute branch part.

The color conversion display panel may further include at least one of a light filter layer, an over-coating layer, and a polarization layer positioned between the color conversion layer and the thin film transistor array panel and between the transmissive layer and the thin film transistor array panel.

A display device according to an exemplary embodiment includes: a thin film transistor array panel; a color conversion display panel overlapping the thin film transistor array panel; and a liquid crystal layer positioned between the thin film transistor array panel and the color conversion display panel and including a plurality of liquid crystal molecules. The color conversion display panel includes a color conversion layer including a semiconductor nanocrystal and a transmissive layer. The thin film transistor array panel includes a first pixel electrode including a first vertical stem part, a first horizontal stem part, and a first minute branch part; a second pixel electrode adjacent to the first pixel electrode and including a second vertical stem part, a second horizontal stem part, and a second minute branch part; and a shielding electrode positioned between the first pixel electrode and the second pixel electrode, and liquid crystal molecules positioned between the first vertical stem part and the shielding electrode are arranged parallel to liquid crystal molecules overlapping the first minute branch part.

The shielding electrode may include a first shielding electrode and a second shielding electrode configured to receive different voltages. The first shielding electrode may be positioned between the first pixel electrode and the second pixel electrode and the second shielding electrode may be positioned adjacent to the first pixel and separated from the first shielding electrode.

The first shielding electrode may be configured to receive a voltage larger than a voltage that the second shielding electrode is configured to receive.

The first minute branch part may overlap the color conversion layer and the transmissive layer.

The color conversion display panel may further include a light blocking member positioned between the color conversion layer and the transmissive layer, and the light blocking member may overlap the shielding electrode.

The color conversion display panel may further include a light blocking member positioned between the color conversion layer and the transmissive layer. The light blocking member may overlap the shielding electrode.

The liquid crystal layer overlapping the first pixel electrode may include two domains in which the arrangement directions of the liquid crystal molecules are different.

The first pixel electrode and the second pixel electrode may be symmetrical with reference to the first shielding electrode.

The first shielding electrode, the second shielding electrode, and the first pixel electrode are positioned on a same layer.

The first shielding electrode may be configured to receive a higher voltage than a voltage applied to the first pixel electrode. The second shielding electrode may be configured to receive a voltage that is the same as or lower than the voltage applied to the first pixel electrode.

A plurality of first shielding electrodes may be connected to each other, and a plurality of second shielding electrodes may be connected to each other.

Additional features of the inventive concepts will be set forth in the description which follows, and in part will be apparent from the description, or may be learned by practice of the inventive concepts.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate exemplary embodiments of the invention, and together with the description serve to explain the inventive concepts.

FIG. 1 is a schematic top plan view of a display device according to an exemplary embodiment.

FIG. 2 is a top plan view of a plurality of pixels according to an exemplary embodiment.

FIG. 3 is a cross-sectional view taken along a line of FIG. 2.

FIG. 4 is a view to schematically explain a movement of a liquid crystal molecule according to an exemplary embodiment of FIG. 2.

FIG. 5 is a view to schematically explain a movement of a liquid crystal molecule according to a comparative example.

FIG. 6 is a top plan view of a pixel of a display device according to a variation in the exemplary embodiment of FIG. 2.

FIG. 7 is a luminance simulation image of a pixel according to Comparative Example 1, Comparative Example 2, Comparative Example 3, Exemplary Embodiment 1, and Exemplary Embodiment 2.

### DETAILED DESCRIPTION

In the following description, for the purposes of explanation, numerous specific details are set forth in order to provide a thorough understanding of various exemplary embodiments or implementations of the invention. As used herein “embodiments” and “implementations” are interchangeable words that are non-limiting examples of devices or methods employing one or more of the inventive concepts disclosed herein. It is apparent, however, that various exemplary embodiments may be practiced without these specific details or with one or more equivalent arrangements. In other instances, well-known structures and devices are shown in block diagram form in order to avoid unnecessarily obscuring various exemplary embodiments. Further, various exemplary embodiments may be different, but do not have to be exclusive. For example, specific shapes, configurations, and characteristics of an exemplary embodiment may be used or implemented in another exemplary embodiment without departing from the inventive concepts.

Unless otherwise specified, the illustrated exemplary embodiments are to be understood as providing exemplary features of varying detail of some ways in which the inventive concepts may be implemented in practice. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the inventive concepts.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an exemplary embodiment may be implemented differently, a specific process order may be performed differently from the described order. For example, two consecutively described processes may be performed substantially at the same time or performed in an order opposite to the described order. Also, like reference numerals denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the first direction, the second direction, and the third direction are not limited to three axes of a rectangular coordinate system, such as the x, y, and z-axes, and may be interpreted in a broader sense. For example, the first direction, the second direction, and the third direction may be perpendicular to one another, or may represent different directions that are not perpendicular to one another. For the purposes of this disclosure, “at least one of X, Y, and Z” and “at least one selected from the group consisting of X, Y, and Z” may be construed as X only, Y only, Z only, or any combination of two or more of X, Y, and Z, such as, for instance, XYZ, XYY, YZ, and ZZ. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various exemplary embodiments are described herein with reference to sectional and/or exploded illustrations that are schematic illustrations of idealized exemplary embodiments and/or intermediate structures. As such, variations from the shapes of the illustrations as a result, for example, of manufacturing techniques and/or tolerances, are to be expected. Thus, exemplary embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

Unless otherwise defined, all terms (including technical and scientific terms) used herein have the same meaning as commonly understood by one of ordinary skill in the art to which this disclosure is a part. Terms, such as those defined in commonly used dictionaries, should be interpreted as having a meaning that is consistent with their meaning in the context of the relevant art and should not be interpreted in an idealized or overly formal sense, unless expressly so defined herein.

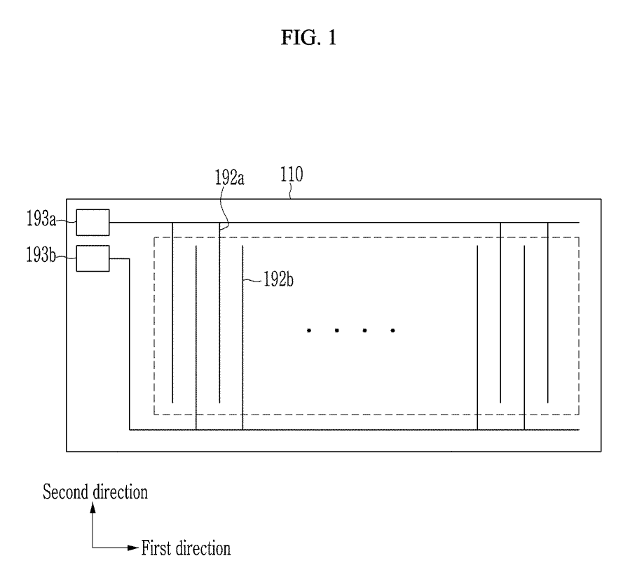

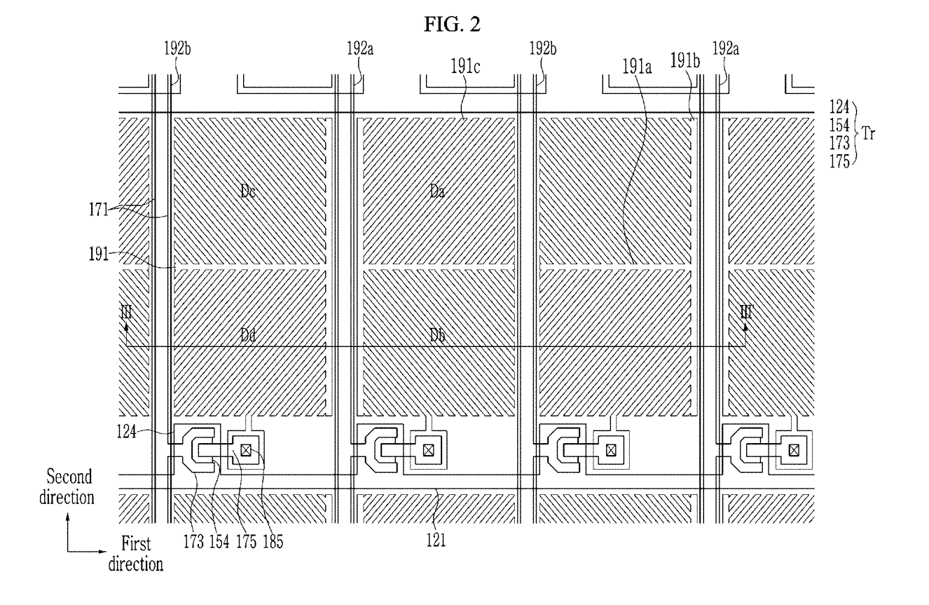

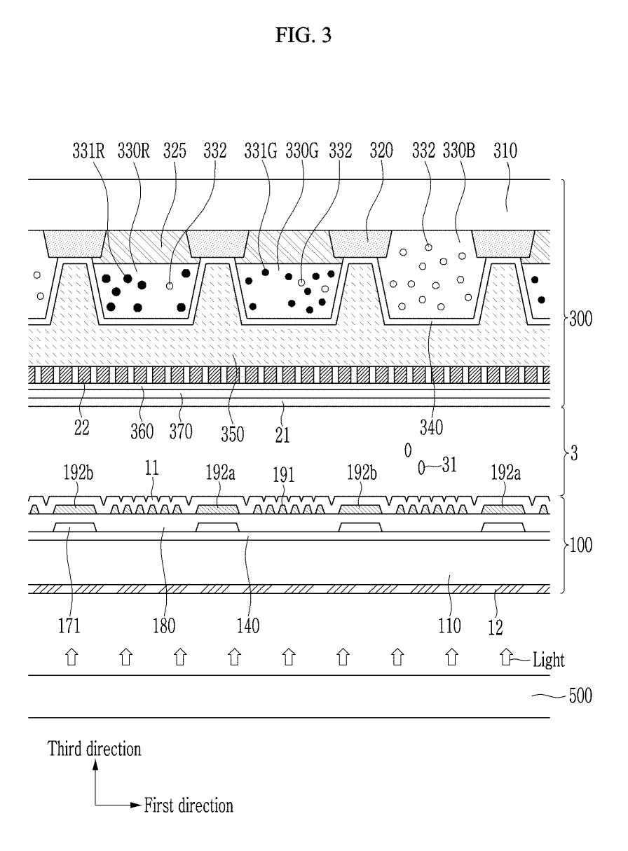

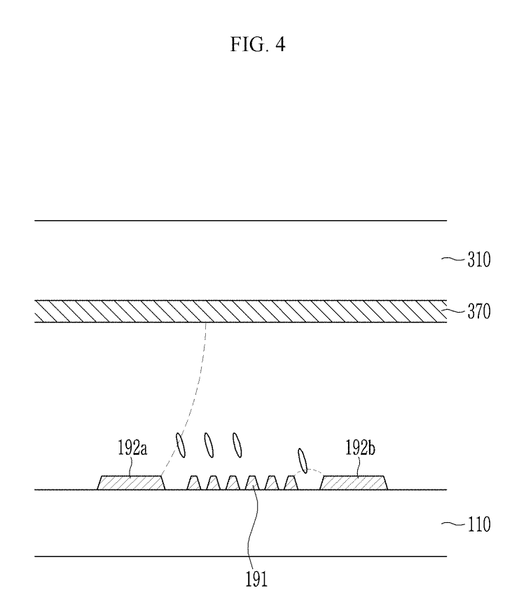

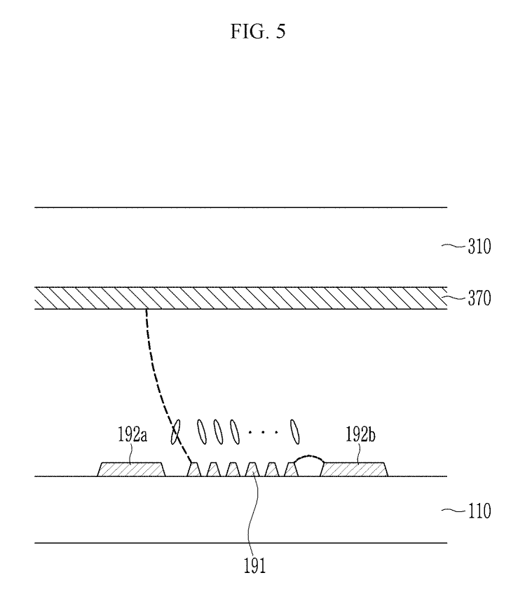

Now, a display device according to an exemplary embodiment will be described with reference to FIG. 1, FIG. 2, FIG. 3, FIG. 4, and FIG. 5. FIG. 1 is a schematic top plan view of a display device according to an exemplary embodiment. FIG. 2 is a top plan view of a plurality of pixels according to an exemplary embodiment. FIG. 3 is a cross-sectional view taken along a line III-III′ of FIG. 2. FIG. 4 is a view to schematically explain a movement of liquid crystal molecules according to an exemplary embodiment of FIG. 2. FIG. 5 is a view to schematically explain a movement of liquid crystal molecules according to a comparative example.

First, referring to FIG. 1, the display device according to an exemplary embodiment of the present invention may include a first shielding electrode 192a and a second shielding electrode 192b positioned on a first substrate 110. The first shielding electrode 192a and the second shielding electrode 192b may be alternately positioned along a first direction (a gate line extending direction) and may have a shape extends along a second direction (a data line extending direction).

The plurality of first shielding electrodes 192a included in the display device may be connected to each other and receive a predetermined first voltage through a first pad part 193a. The plurality of second shielding electrodes 192b may receive a predetermined second voltage through a second pad part 193b. The first voltage and the second voltage may be different, and as an example, the first voltage may be larger than the second voltage.

Next, the structure of the display device will be described in detail with reference to FIG. 2 and FIG. 3.

The display device according to an exemplary embodiment includes a light unit 500, a thin film transistor array panel 100, a color conversion display panel 300 separated from and overlapping the thin film transistor array panel 100, and a liquid crystal layer 3 positioned between the thin film transistor array panel 100 and the color conversion display panel 300.

The light unit 500 is positioned at a rear surface of the thin film transistor array panel 100 along a third direction. The light unit 500 may include a light source generating light, and a light guide (not shown) receiving the light and guiding the received light toward the thin film transistor array panel 100.

The light unit 500 may include any light source emitting blue light, and may include a light emitting diode (LED) as an example. Instead of the light unit 500 including the blue light source, the light unit 500 may include a white light source or an ultraviolet ray light source. However, the display device using the light unit 500 including the blue light source will be described hereinafter.

The light source may be an edge type disposed on at least one lateral surface of the light guide or a direct type positioned directly below the light guide, but is not limited thereto.

The thin film transistor array panel 100 includes a first polarization layer 12 positioned between the first substrate 110 and the light unit 500. The first polarization layer 12 polarizes light incident from the light unit 500 to the first substrate 110.

The first polarization layer 12 may be at least one of a deposited polarization layer, a coated polarization layer, and a printed polarization layer, but is not limited thereto. As an example, it may be a wire grid polarizer and but is not limited thereto.

The thin film transistor array panel 100 may include a gate line 121 extending in a first direction between the first substrate 110 and the liquid crystal layer 3 and including a gate electrode 124, a gate insulating layer 140 positioned between a gate line 121 and the liquid crystal layer 3, a semiconductor layer 154 positioned between the gate insulating layer 140 and the liquid crystal layer 3, a data line 171 positioned between the semiconductor layer 154 and the liquid crystal layer 3 and extending in a second direction, a source electrode 173 connected to the data line 171, a drain electrode 175 separated from the source electrode 173, and a passivation layer 180 positioned between the data line 171 and the liquid crystal layer 3.

The semiconductor layer 154 forms a channel in a part that is not covered by the source electrode 173 and the drain electrode 175. The gate electrode 124, the semiconductor layer 154, the source electrode 173, and the drain electrode 175 form one thin film transistor Tr.

A pixel electrode 191 is positioned on the passivation layer 180. The pixel electrode 191 may be physically and electrically connected to the drain electrode 175 through a contact hole 185 included in the passivation layer 180.

The pixel electrode 191 according to an exemplary embodiment includes a horizontal stem part 191a, a vertical stem part 191b connected to the horizontal stem part 191a to be crossed therewith, and a plurality of minute branch parts 191c extending from the horizontal stem part 191a and the vertical stem part 191b along a diagonal direction. The horizontal stem part 191a according to an exemplary embodiment may be connected to the vertical stem part 191b to be crossed therewith at a center of the vertical stem part 191b. The minute branch part 191c forms an angle of about 45 degrees or 135 degrees with the horizontal stem part 191a. The minute branch parts 191c extending in different diagonal directions from each other may be crossed with each other.

One pixel electrode 191 may include a first region Da and a second region Db divided with reference to the horizontal stem part 191a and the vertical stem part 191b. Arrangement directions of liquid crystal molecules 31 may be different in the first region Da and the second region Db. In detail, a side of the minute branch part 191c distorts an electric field to form a horizontal component determining an inclination direction of the liquid crystal molecules 31. The horizontal component of the electric field may be substantially parallel to the side of the minute branch parts 191c. The liquid crystal molecules 31 may be inclined along a direction parallel to a length direction of the minute branch parts 191c. Because one pixel electrode 191 includes the minute branch parts 191c that are inclined in two different directions from each other, the directions in which the liquid crystal molecules 31 are inclined may be two directions. Two domains having the different alignment directions of the liquid crystal molecules 31 may be formed in the liquid crystal layer 3.

The first shielding electrode 192a and the second shielding electrode 192b may be positioned on the same layer as the pixel electrode 191. The first shielding electrode 192a and the second shielding electrode 192b are disposed to be separated from the pixel electrode 191 and extend to be substantially parallel to the data line 171. The first shielding electrode 192a and the second shielding electrode 192b overlap the data line 171. The first shielding electrode 192a and the second shielding electrode 192b may be alternately disposed along the first direction.

The first shielding electrode 192a and the second shielding electrode 192b may include the same material as the pixel electrode 191. The first shielding electrode 192a and the second shielding electrode 192b may be simultaneously formed in a process forming the pixel electrode 191, but are not limited thereto.

The first shielding electrode 192a and the second shielding electrode 192b may receive different voltages from each other. According to an exemplary embodiment, the first shielding electrode 192a may receive a first voltage that is higher than a voltage applied to the pixel electrode 191, and the second shielding electrode 192b may receive a second voltage that has a same level as or a lower than the voltage applied to the pixel electrode 191.

The vertical stem part 191b of the pixel electrode 191 may be positioned to be adjacent to the first shielding electrode 192a receiving the higher voltage than the voltage applied to the pixel electrode 191. One pixel positioned at the right of the first shielding electrode 192a with reference to the first shielding electrode 192a may include the vertical stem part 191b positioned to be adjacent to the first shielding electrode 192a, and one pixel positioned at the left of the first shielding electrode 192a may also include the vertical stem part 191b positioned to be adjacent to the first shielding electrode 192a. The shape of the pixel electrodes 191 positioned at the left and the right with reference to the first shielding electrode 192a may be symmetrical.

Two pixel electrodes 191 positioned between two adjacent second shielding electrodes 192b may include four domains where the liquid crystal molecules 31 are arranged in the different directions from each other. Two pixel electrodes 191 positioned at respective sides with reference to the first shielding electrode 192a may include four domains Da, Db, Dc, and Dd where the liquid crystal molecules 31 are arranged in the different directions from each other.

In detail, the pixel electrode 191 positioned at the right with reference to the first shielding electrode 192a may include minute branch parts 191c extending in the right/upper direction and minute branch parts 191c extending in the right/lower direction. Also, the pixel electrode 191 positioned at the left with reference to the first shielding electrode 192a may include minute branch parts 191c extending in the left/upper direction and minute branch parts 191c extending in the left/lower direction. The liquid crystal layer 3 overlapping two adjacent pixel electrodes 191 may include four domains Da, Db, Dc, and Dd divided depending on the arrangement direction of the liquid crystal molecules 31.

Hereinafter, the movement of the liquid crystal molecules 31 of the above-described display device including the pixel electrode 191 and the shielding electrodes 192a and 192b will be described.

Referring to FIG. 4, when the first voltage that is higher than the voltage applied to the pixel electrode 191 is applied to the first shielding electrode 192a, a fringe field of a front direction is strongly formed. Accordingly, the liquid crystal molecules 31 positioned between the first shielding electrode 192a and the vertical stem part may be arranged in the direction parallel to the liquid crystal molecules 31 arranged by the minute branch parts. The luminance of the display device may be improved through the same arrangement of the liquid crystal molecules 31 on the boundary of the first shielding electrode 192a and the pixel electrode 191.

Also, when the second voltage that is lower than the voltage applied to the pixel electrode 191 is applied to the second shielding electrode 192b, a fringe field of a reverse direction generated on the boundary between the pixel electrode 191 and the second shielding electrode 192b may be weak. As the liquid crystal molecules 31 positioned between the second shielding electrode 192b and the pixel electrode 191 are arranged parallel to the liquid crystal molecules 31 arranged by the minute branch parts, the luminance of the display device may be improved.

As shown in FIG. 5, when the same voltage (as one example, a common voltage) is applied to the first shielding electrode 192a and the second shielding electrode 192b, the arrangement directions of the liquid crystal molecules 31 positioned between the vertical stem part and the first shielding electrode 192a and the liquid crystal molecules 31 overlapping the minute branch part are collapsed such that a dark part may be generated. The luminance of the display device may be reduced by the dark part.

According to an exemplary embodiment of the present invention, as the liquid crystal molecules 31 are effectively arranged to the region where the shielding electrodes 192a and 192b are adjacent (where the arrangement control of the liquid crystal molecules 31 is not easy), as well as the region where the minute branch parts 191c are positioned, the display device with improved luminance may be provided.

A first alignment layer 11 may be positioned between the pixel electrode 191 and the liquid crystal layer 3 and between the shielding electrodes 192a and 192b and the liquid crystal layer 3.

The color conversion display panel 300 includes a substrate 310 overlapping the thin film transistor array panel 100. A light blocking member 320 is positioned between the substrate 310 and the thin film transistor array panel 100. In detail, the light blocking member 320 is positioned between the substrate 310 and later-described color conversion layers 330R and 330G and between the substrate 310 and a later-described transmissive layer 330B.

The light blocking member 320 may be positioned between the red color conversion layer 330R and the green color conversion layer 330G, between the green color conversion layer 330G and the transmissive layer 330B, and between the transmissive layer 330B and the red color conversion layer 330R along the first direction. Also, the light blocking member 320 may be positioned between the red color conversion layer 330R and the red color conversion layer 330R adjacent to each other in the second direction, between the green color conversion layer 330G and the green color conversion layer 330G adjacent to each other in the second direction, and between the transmissive layer 330B and the transmissive layer 330B adjacent to each other in the second direction. The light blocking member 320 may have a lattice shape or a straight line shape in plan view or when view from above.

The light blocking member 320 may prevent a mixture of different colors emitted from adjacent pixels and define regions where the red color conversion layer 330R, the green color conversion layer 330G, and the transmissive layer 330B are disposed. The light blocking member 320 may use any material to block (reflect or absorb) the light.

A blue light cutting filter 325 may be positioned between the substrate 310 and the light blocking member 320, and the thin film transistor array panel 100. The blue light cutting filter 325 may be positioned between the red color conversion layer 330R and the substrate 310 and between the green color conversion layer 330G and the substrate 310. The blue light cutting filter 325 may not overlap a region emitting blue light where the transmissive layer 330B is positioned.

The blue light cutting filter 325 may include a first region overlapping the red color conversion layer 330R and a second region overlapping the green color conversion layer 330G, and the regions may be connected to each other. However, it is not limited thereto, and the first region and the second region may be formed to be separated from each other. When the first region and the second region are separated from each other, the separated blue light cutting filters 325 may include different materials from each other.

The blue light cutting filter 325 may block blue light supplied from the light unit 500. The blue light incident from the light unit 500 to the red color conversion layer 330R and the green color conversion layer 330G may be converted into red or green light by semiconductor nanocrystals 331R and 331G, and some blue light may be emitted as it is without the conversion. The blue light emitted without the conversion is mixed with the red light or the green light, thus the color reproducibility may be deteriorated. The blue light cutting filter 325 may block (absorb or reflect) blue light supplied from the light unit 500 from being emitted through the substrate 310 without being absorbed in the red color conversion layer 330R and the green color conversion layer 330G.

The blue light cutting filter 325 may include any material capable of obtaining the above-described effects, and as one example, may include a yellow color filter. The blue light cutting filter 325 may have a stacked structure of a single layer or multiple layers.

In exemplary embodiments, the blue light cutting filter 325 contacting the substrate 310 is shown, but the present invention is not limited thereto, and a separate buffer layer may be positioned between the substrate 310 and blue light cutting filter 325.

The plurality of the color conversion layers 330R and 330G and the transmissive layer 330B may be positioned between the substrate 310 and the thin film transistor array panel 100. The plurality of the color conversion layers 330R and 330G and the transmissive layer 330B may be alternately arranged along the first direction.

The plurality of the color conversion layers 330R and 330G may convert incident light into light having a different wavelength from that of the incident light, and emit the converted light. The plurality of the color conversion layers 330R and 330G may include the red color conversion layer 330R and the green color conversion layer 330G. The incident light is not converted in the transmissive layer 330B, and the incident light may be emitted as it is. As an example, blue light may be incident on the transmissive layer 330B, and may be emitted as it is.

The red color conversion layer 330R may include the first semiconductor nanocrystal 331R that converts incident blue light into red light. The first semiconductor nanocrystal 331R may include at least one of a phosphor and a quantum dot.

The green color conversion layer 330G may include the second semiconductor nanocrystal 331G that coverts incident blue light into green light. The second semiconductor nanocrystal 331G may include at least one of a phosphor and a quantum dot.

The quantum dot included in the first semiconductor nanocrystal 331R and the second semiconductor nanocrystal 331G may be independently selected from a Group II-VI compound, a Group III-V compound, a Group IV-VI compound, a Group IV element, a Group IV compound, and a combination thereof.

The Group II-VI compound may be a two-element compound selected from CdSe, CdTe, ZnS, ZnSe, ZnTe, ZnO, HgS, HgSe, HgTe, MgSe, MgS, and a mixture thereof; a three-element compound selected from CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and a mixture thereof; and a four-element compound selected from HgZnTeS, CdZnSeS, CdZnSeTe, CdZnSTe, CdHgSeS, CdHgSeTe, CdHgSTe, HgZnSeS, HgZnSeTe, HgZnSTe, and a mixture thereof. The Group III-V compound may be a two-element compound selected from GaN, GaP, GaAs, GaSb, AlN, AlP, AlAs, AlSb, InN, InP, InAs, InSb, and a mixture thereof; a three-element compound selected from GaNP, GaNAs, GaNSb, GaPAs, GaPSb, AlNP, AlNAs, AlNSb, AlPAs, AlPSb, InNP, InNAs, InNSb, InPAs, InPSb, and a mixture thereof; and a four-element compound selected from GaAlNAs, GaAlNSb, GaAlPAs, GaAlPSb, GaInNP, GaInNAs, GaInNSb, GaInPAs, GaInPSb, GaAlNP, InAlNP, InAlNAs, InAlNSb, InAlPAs, InAlPSb, and a mixture thereof. The Group IV-VI compound may be a two-element compound selected from SnS, SnSe, SnTe, PbS, PbSe, PbTe, and a mixture thereof; a three-element compound selected from SnSeS, SnSeTe, SnSTe, PbSeS, PbSeTe, PbSTe, SnPbS, SnPbSe, SnPbTe, and a mixture thereof; and a four-element compound selected from SnPbSSe, SnPbSeTe, SnPbSTe, and a mixture thereof. The Group IV element may be selected from Si, Ge, and a mixture thereof. The Group IV compound may be a two-element compound selected from SiC, SiGe, and a mixture thereof.

In this case, the two-element compound, the three-element compound, or the four-element compound may be present in particles at uniform concentrations, or they may be divided into states having partially different concentrations to be present in the same particle, respectively. In addition, a core/shell structure in which some quantum dots enclose some other quantum dots may be possible. An interface between the core and the shell may have a concentration gradient in which a concentration of elements of the shell decreases closer to its center.

The quantum dot may have a full width at half maximum (FWHM) of the light-emitting wavelength spectrum that is equal to or less than about 45 nm, preferably equal to or less than about 40 nm, and more preferably equal to or less than about 30 nm, and in this range, color purity or color reproducibility may be improved. In addition, since light emitted through the quantum dot is emitted in all directions, a viewing angle of light may be improved.

When the first semiconductor nanocrystal 331R includes a red phosphor, the red phosphor may include at least one selected from a group including (Ca, Sr, Ba)S, (Ca, Sr, Ba)₂Si₅N₈, CaAlSiN₃, CaMoO₄, and Eu₂Si₅N₈, and but the present disclosure is not limited thereto.

When the second semiconductor nanocrystal 331G includes a green phosphor, the green phosphor may include at least one selected from a group including yttrium aluminum garnet (YAG), (Ca, Sr, Ba)₂SiO₄, SrGa₂S₄, BAM, α-SiAlON, β-SiAlON, Ca₃Sc₂Si₃O₁₂, Tb₃Al₅O₁₂, BaSiO₄, CaAlSiON, and (Sr₍₁₋ₓ₎Baₓ)Si₂O₂N₂, but the present disclosure is not limited thereto. The x may be any number between 0 and 1.

The transmissive layer 330B may pass incident light as it is. The transmissive layer 330B may include a resin passing blue light. The transmissive layer 330B positioned at the region emitting the blue light does not include the separate semiconductor nanocrystal, and passes the incident blue as it is.

Although not shown, the transmissive layer 330B may further include at least one of a dye and a pigment. The transmissive layer 330B including the dye or pigment may reduce the external light reflection, and may provide the blue light with improved color purity.

At least one of the red color conversion layer 330R, the green color conversion layer 330G, and the transmissive layer 330B may further include scatterers 332. Contents of respective scatterers 332 included in the red color conversion layer 330R, the green color conversion layer 330G, and the transmissive layer 330B may be different.

The scatterers 332 may increase an amount of light that is converted in or passes through the color conversion layers 330R and 330G and the transmissive layer 330B, and may uniformly provide front luminance and lateral luminance.

The scatterer 332 may include any material capable of evenly scattering incident light. As an example, the scatterer 332 may include at least one among TiO₂, ZrO₂, Al₂O₃, In₂O₃, ZnO, SnO₂, Sb₂O₃, and ITO.

As one example, the red color conversion layer 330R, the green color conversion layer 330G, and the transmissive layer 330B may include a photosensitive resin, and may be formed through a photolithography process. In addition, they may be formed through a printing process or an inkjet process, and in the case of these processes, the red color conversion layer 330R, the green color conversion layer 330G, and the transmissive layer 330B may include a material that is not the photosensitive resin. In exemplary embodiments, although it is described that the color conversion layer and the transmissive layer are formed through the photolithography process, the printing process, or the inkjet process, the present invention is not limited thereto.

A light filter layer 340 is positioned between the color conversion layers 330R and 330G and an over-coating layer 350 and between the transmissive layer 330B and the over-coating layer 350.

The light filter layer 340 may be a filter transmitting light of a predetermined wavelength, and reflecting or absorbing light except for that of the predetermined wavelength. The light filter layer 340 may have a structure in which layers having a high refractive index and layers having a low refractive index are alternately stacked, and may utilize reinforcement and/or destructive interference between these layers to transmit and/or reflect the predetermined wavelength as above-described.

The light filter layer 340 may include at least one of TiO₂, SiNₓ, SiO_{y}, TiN, AlN, Al₂O₃, SnO₂, WO₃, and ZrO₂, and as one example, it may have a structure in which SiNₓ and SiO_{y} are alternately stacked. The x and y may be adjusted according to process conditions for forming the layers as factors for determining a chemical composition ratio in SiNₓ and SiO_{y}.

In some exemplary embodiments, the light filter layer 340 may be omitted, and it may be replaced with a low refractive layer or the like.

The over-coating layer 350 is positioned between the light filter layer 340 and the thin film transistor array panel 100. The over-coating layer 350 may overlap a front surface of the substrate 310.

The over-coating layer 350 may flatten a surface of one of the red color conversion layer 330R, the green color conversion layer 330G, and the transmissive layer 330B. The over-coating layer 350 includes an organic material, but is not limited thereto, and may include any material having the flattening function.

A second polarization layer 22 may be positioned between the over-coating layer 350 and the liquid crystal layer 3. The second polarization layer 22 may be formed by any method of a deposited polarization layer, a coated polarization layer, and a printed polarization layer. As one example, a wire grid polarizer may be used. When the second polarization layer 22 is the wire grid polarization layer, the second polarization layer 22 may include a plurality of bars having a width of several nanometers.

An insulating layer 360, a common electrode 370, and a second alignment layer 21 are positioned between the second polarization layer 22 and the liquid crystal layer 3.

The insulating layer 360 as a layer insulating the second polarization layer 22 and the common electrode 370 of the metal material may be omitted when the second polarization layer 22 is not a metal material. The common electrode 370 receiving the common voltage may form an electric field with the above-described pixel electrode 191. The configuration in which the common electrode 370 is positioned in a different display panel from that of the pixel electrode 191 is described in the exemplary embodiments, but is not limited thereto, and they may be included in the same display panel.

The liquid crystal layer 3 is positioned between the thin film transistor array panel 100 and the color conversion display panel 300, and includes a plurality of liquid crystal molecules 31. It is possible to control transmittance of the light received from the light unit 500 according to a degree of movement of the liquid crystal molecules 31 and the like. The liquid crystal layer 3 according to an exemplary embodiment may further include a reactive mesogen or a polymer of the reactive mesogen.

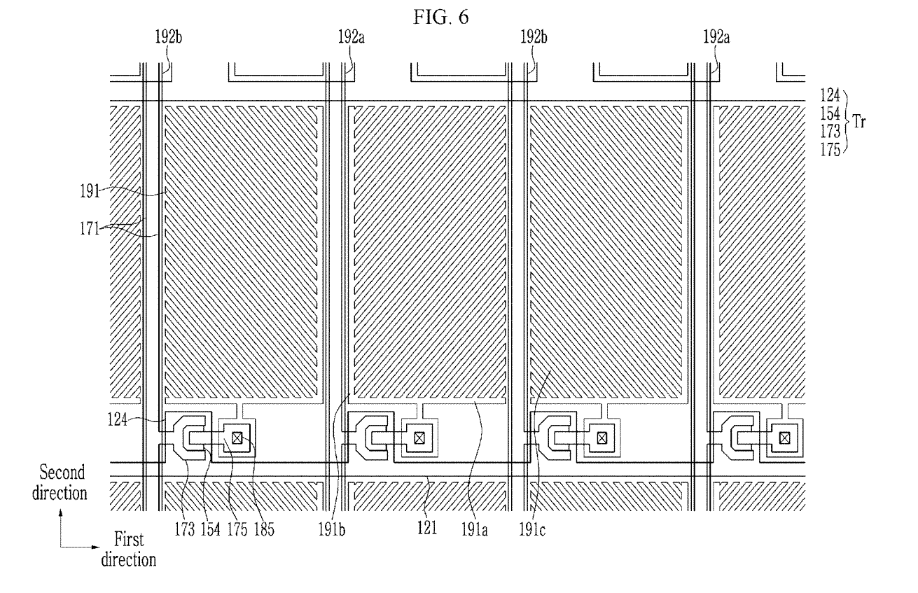

Next, the display device according to a variation exemplary embodiment of the present invention will be described with reference to FIG. 6. FIG. 6 is a top plan view of a pixel of a display device according to a variation in the exemplary embodiment of FIG. 2. The description for the same constituent elements described with reference to FIG. 2, FIG. 3, and FIG. 4 is omitted.

Referring to FIG. 6, the pixel electrode 191 includes the horizontal stem part 191a, the vertical stem part 191b, and the minute branch parts 191c extending from the horizontal stem part 191a and the vertical stem part 191b along the diagonal direction. According to an exemplary embodiment, the horizontal stem parts 191a may be connected to the end of the vertical stem part 191b to be crossed therewith. One pixel electrode 191 may include a plurality of minute branch parts 191c extending from the horizontal stem part 191a and the vertical stem part 191b and elongated in one diagonal direction.

The vertical stem part 191b of the pixel electrode 191 may be positioned to be adjacent to the first shielding electrode 192a receiving the higher voltage than the voltage applied to the pixel electrode 191. One pixel positioned at the right of the first shielding electrode 192a with reference to the first shielding electrode 192a may include the vertical stem part 191b positioned to be adjacent to the first shielding electrode 192a, and one pixel positioned at the left of the first shielding electrode 192a may also include the vertical stem part 191b positioned to be adjacent to the first shielding electrode 192a. The shape of the pixel electrodes 191 positioned at the left and the right with reference to the first shielding electrode 192a may be symmetrical.

The liquid crystal layer 3 overlapping two pixel electrodes 191 positioned between two adjacent second shielding electrodes 192b may include may include two domains where the liquid crystal molecules 31 are arranged in the different directions from each other. In detail, the pixel electrode 191 positioned at the right with reference to the first shielding electrode 192a may include the minute branch parts 191c extending in the right/upper direction, and the pixel electrode 191 positioned at the left with reference to the first shielding electrode 192a may include the minute branch parts 191c extending in the left/upper direction. The liquid crystal layer 3 overlapping two adjacent pixel electrodes 191 may include two domains divided depending on the arrangement direction of the liquid crystal molecules 31.

The present specification describes the exemplary embodiment in which the different voltages are applied to the first shielding electrode 192a and the second shielding electrode 192b. However, it is not limited thereto, and the same voltage may be applied to the first shielding electrode 192a and the second shielding electrode 192b. In the exemplary embodiment in which the same voltage (as one example, the common voltage) is applied to the first shielding electrode 192a and the second shielding electrode 192b, a method for controlling the arrangement of the liquid crystal molecules 31 of the initial state in which the voltage is not applied to the pixel electrode 191 and the common electrode 370 is not applied may be used.

According to an exemplary embodiment, in the state in which the voltage is not applied to the pixel electrode 191 and the common electrode 370, the liquid crystal molecules 31 positioned between the first shielding electrode 192a and the adjacent vertical stem part 191b may be parallel to the arrangement of the liquid crystal molecules 31 overlapping the minute branch parts 191c.

In detail, the liquid crystal layer 3 according to the present invention may include the liquid crystal compound and the reactive mesogen. The display device may be manufactured by a method of combining the thin film transistor array panel 100 and the color conversion display panel 300 after dripping the liquid crystal material on the thin film transistor array panel 100 or the color conversion display panel 300.

In the state in which the voltage is applied to the pixel electrode 191 and the common electrode 370 after the combination, an electric field exposure process irradiating light such as ultraviolet rays (UV) is executed. Thus, while the reactive mesogen included in the dripped liquid crystal material moves to the side of the thin film transistor array panel 100 or the color conversion display panel 300, a protrusion including an alignment polymer may be formed. The protrusion may have the pretilt in the direction parallel to the length direction of the minute branch part 191c of the pixel electrode 191 for the liquid crystal molecules 31.

In the electric field exposure process, the first voltage that is higher than the voltage applied to the pixel electrode 191 may be applied to the first shielding electrode 192a, and the second voltage that is lower than or the same level as the voltage applied to the pixel electrode 191 may be applied to the second shielding electrode 192b. Accordingly, as shown in FIG. 4, the initial state in which the arrangement directions of the liquid crystal molecules 31 between the first shielding electrode 192a and the vertical stem part 191b, between the second shielding electrode 192b and the pixel electrode 191, and overlapping the minute branch parts 191c are parallel may be provided.

Any configuration for applying the first voltage to the first shielding electrode 192a and the second voltage to the second shielding electrode 192b In the electric field exposure process, and the same voltage to the first shielding electrode 192a and the second shielding electrode 192b during the driving of the display device, is of course possible. As one example, the substrate 110 includes a pad part applying the same voltage to the first shielding electrode 192a and the second shielding electrode 192b, and a configuration in which a pad part for applying another voltage to the first shielding electrode 192a and the second shielding electrode 192b extends outside the substrate 110 during the manufacturing process and is removed after the manufacturing of the display device is possible.

According to the above-described exemplary embodiment, even if the same voltage is applied to the first shielding electrode 192a and the second shielding electrode 192b during the driving of the display device, the luminance reduction due to the generation of the dark part by the initial state of the liquid crystal molecules 31 may be prevented.

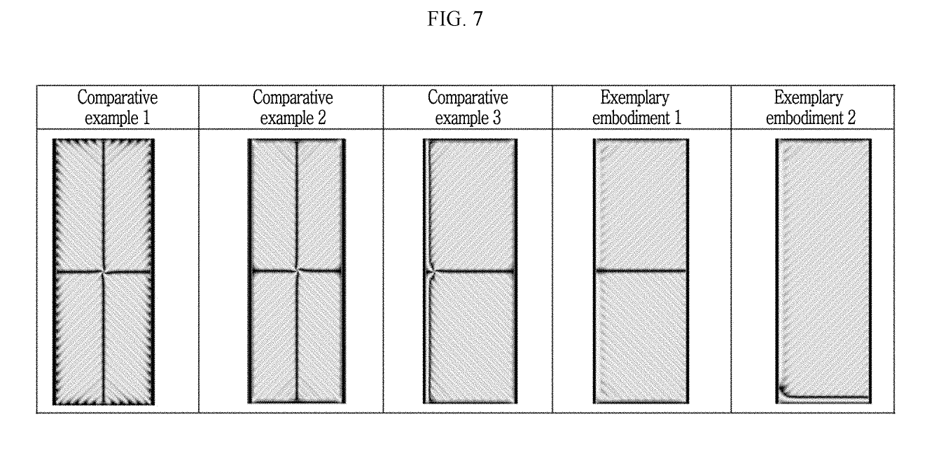

Next, a luminance degree of one pixel according to a comparative example and an exemplary embodiment will be described with reference to FIG. 7. FIG. 7 is a luminance simulation image of a pixel according to Comparative Example 1, Comparative Example 2, Comparative Example 3, Exemplary Embodiment 1, and Exemplary Embodiment 2.

Referring to FIG. 7, Comparative Example 1 is a display device in which the shielding electrode does not exist and the liquid crystal layer overlapping one pixel electrode includes four domains having the different arrangement directions of the liquid crystal molecules. Comparative Example 2 is a display device in which a frame of the pixel electrode has a bound shape and other conditions are the same as Comparative Example 1. Comparative Example 3 is a display device in which the liquid crystal layer overlapping one pixel electrode includes two domains. Exemplary Embodiment 1 is a display device in which the liquid crystal layer overlapping one pixel electrode includes two domains and the first shielding electrode and the second shielding electrode are included according to an exemplary embodiment. Exemplary Embodiment 2 is a display device in which the liquid crystal layer overlapping one pixel electrode includes one domain and the first shielding electrode and the second shielding electrode are included.

As a result of examining the luminance for these, Comparative Example 1 represents about 97% luminance, Comparative Example 2 represents about 100% luminance, and Comparative Example 3 represents 101.4% luminance. Also, Exemplary Embodiment 1 represents about 106.5% luminance, and Exemplary Embodiment 2 represents about 106.7% luminance. Thus, a display device according to an exemplary embodiment has luminance that is improved by about 6% or more compared with the comparative examples.

According to exemplary embodiments, a display device with improved color reproducibility and luminance may be provided.

Although certain exemplary embodiments and implementations have been described herein, other embodiments and modifications will be apparent from this description. Accordingly, the inventive concepts are not limited to such embodiments, but rather to the broader scope of the appended claims and various obvious modifications and equivalent arrangements as would be apparent to a person of ordinary skill in the art.

What is claimed is:

1. A display device, comprising:
a thin film transistor array panel comprising a first pixel electrode connected to a first thin film transistor and a second pixel electrode adjacent to the first pixel electrode and connected to a second thin film transistor; and
a color conversion display panel overlapping the thin film transistor array panel,
wherein the color conversion display panel comprises a color conversion layer comprising a semiconductor nanocrystal and a transmissive layer,
wherein the thin film transistor array panel comprises a first shielding electrode positioned between the first pixel electrode and the second pixel electrode and a second shielding electrode positioned adjacent to the first pixel electrode and separated the first shielding electrode, and
wherein the first shielding electrode and the second shielding electrode are configured to receive different voltages.

2. The display device of claim 1, wherein the first shielding electrode is configured to receive a voltage that is larger than a voltage that the second shielding electrode is configured to receive.

3. The display device of claim 1, wherein the first shielding electrode is configured to receive a higher voltage than a voltage applied to the first pixel electrode, and the second shielding electrode is configured to receive a voltage that is the same as or lower than the voltage applied to the first pixel electrode.

4. The display device of claim 1, wherein:
the first pixel electrode comprises a first vertical stem part, a first horizontal stem part, and a first minute branch part, and
the first pixel electrode is positioned between the first shielding electrode and the second shielding electrode, and the first vertical stem part is positioned adjacent to the first shielding electrode.

5. The display device of claim 4, wherein the first horizontal stem part is orthogonal at a center of the first vertical stem part.

6. The display device of claim 5, wherein a liquid crystal layer overlapping the first pixel electrode comprises two domains of liquid crystal molecules with different arrangement directions of the liquid crystal molecules.

7. The display device of claim 4, wherein:
the second pixel electrode comprises a second vertical stem part, a second horizontal stem part, and a second minute branch part,
the second pixel electrode is positioned between the first shielding electrode and a different second shielding electrode, and the second vertical stem part of the second pixel electrode is positioned adjacent to the first shielding electrode, and
the first pixel electrode and the second pixel electrode are symmetrical with reference to the first shielding electrode.

8. The display device of claim 1, wherein the first shielding electrode, the second shielding electrode, the first pixel electrode are positioned on a same layer.

9. The display device of claim 4, wherein liquid crystal molecules positioned between the first vertical stem part and the first shielding electrode are arranged parallel to liquid crystal molecules overlapping the first minute branch part.

10. The display device of claim 1, wherein the color conversion display panel further comprises at least one of a light filter layer, an over-coating layer, and a polarization layer positioned between the color conversion layer and the thin film transistor array panel and between the transmissive layer and the thin film transistor array panel.

11. A display device, comprising:
a thin film transistor array panel;
a color conversion display panel overlapping the thin film transistor array panel; and
a liquid crystal layer positioned between the thin film transistor array panel and the color conversion display panel and comprising a plurality of liquid crystal molecules,
wherein the color conversion display panel comprises a color conversion layer comprising a semiconductor nanocrystal and a transmissive layer,
wherein the thin film transistor array panel comprises:
a first pixel electrode comprising a first vertical stem part, a first horizontal stem part, and a first minute branch part;
a second pixel electrode adjacent to the first pixel electrode and comprising a second vertical stem part, a second horizontal stem part, and a second minute branch part; and
a shielding electrode positioned between the first pixel electrode and the second pixel electrode, and
liquid crystal molecules positioned between the first vertical stem part and the shielding electrode are arranged parallel to liquid crystal molecules overlapping the first minute branch part.

12. The display device of claim 11, wherein:
the shielding electrode comprises a first shielding electrode and a second shielding electrode configured to receive different voltages, and
the first shielding electrode is positioned between the first pixel electrode and the second pixel electrode and the second shielding electrode is positioned adjacent to the first pixel electrode and separated from the first shielding electrode.

13. The display device of claim 12, wherein a voltage applied to the first shielding electrode is configured to receive a voltage larger than a voltage that the second shielding electrode is configured to receive.

14. The display device of claim 11, wherein the first minute branch part overlaps the color conversion layer and the transmissive layer.

15. The display device of claim 11, wherein:
the color conversion display panel further comprises a light blocking member positioned between the color conversion layer and the transmissive layer, and
the light blocking member overlaps the shielding electrode.

16. The display device of claim 11, wherein the liquid crystal layer overlapping the first pixel electrode comprises two domains in which arrangement directions of the liquid crystal molecules are different.

17. The display device of claim 12, wherein the first pixel electrode and the second pixel electrode are symmetrical with reference to the first shielding electrode.

18. The display device of claim 12, wherein
the first shielding electrode, the second shielding electrode, and the first pixel electrode are positioned on a same layer.

19. The display device of claim 12, wherein the first shielding electrode is configured to receives a higher voltage than a voltage applied to the first pixel electrode, and the second shielding electrode is configured to receive a voltage that is the same as or lower than the voltage applied to the first pixel electrode.

20. The display device of claim 12, further comprising a plurality of the first shielding electrodes are connected to each other, and a plurality of the second shielding electrodes are connected to each other.
